(19) United States
(12) Patent Application Publication
(10) Pub. No.: US 2008/0296628 A1
(43) Pub. Date: Dec. 4, 2008

(54) SEMICONDUCTOR INTEGRATED CIRCUIT AND METHOD FOR MANUFACTURING SAME

(75) Inventor: Yoshio Kaneko, Chiba-ken (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/127,905

(22) Filed: May 28, 2008

(30) Foreign Application Priority Data
Jun. 1, 2007 (JP) 2007-146582

(51) Int. Cl. H01L 21/26; H01L 27/105

(52) U.S. Cl. 257/202; 438/795; 257/E27.081; 257/E21.328

(57) ABSTRACT

A semiconductor integrated circuit includes at least one first circuit portion and at least one second circuit portion. The first circuit portion includes a first interconnect or a diffusion layer formed by exposure using a high-precision mask. The second circuit portion includes a second interconnect or a diffusion layer formed by exposure using a first low-precision mask having a lower precision than the high-precision mask.

### CROSS-REFERENCE TO RELATED APPLICATIONS

This application is based upon and claims the benefit of priority from the prior Japanese Patent Application No. 2007-146582, filed on Jun. 1, 2007; the entire contents of which are incorporated herein by reference.

### BACKGROUND OF THE INVENTION

1. Field of the Invention

This invention relates to a semiconductor integrated circuit such as an embedded array and a structured ASIC.

2. Background Art

An embedded array is a kind of semi-custom LSI and includes arrayed transistors available for constructing a circuit with aluminum interconnects, like a gate array except for dedicated circuit blocks. Thus, once the specification requirements of the dedicated circuit blocks are fixed, layout design up to the diffusion layer can be made, and the LSI manufacturing process can be advanced by fabricating masks.

After the final design is completed, the customer only needs to fabricate masks for processes subsequent to the aluminum process to continue the LSI manufacturing process, and the turnaround time for prototypes can be shortened by that amount. However, the number of dedicated masks required is the same as that for manufacturing custom LSIs. The downscaling trend in semiconductor integrated circuits is relentless, and the degree of circuit integration grows year by year. However, mask patterns, which provide design data supporting the increase in the degree of integration, are also becoming finer and finer, presenting the problem of high mask price. Today, a mask set (including several ten masks) for one product costs 50 to 100 million yen or more. The problem is not serious for products such as memory, where the same products are marketed in high volume. However, like custom LSIs, when the purpose is limited to one product for one customer, the number of products consumed is also limited, and the development cost including mask fabrication cost becomes much higher than the unit price of actual LSIs, making many customers feel reluctant to pursue the development. Furthermore, because the mask price increases twice or more each time the generation of semiconductor integrated circuits advances, the problem may possibly become more serious in the future.

FPGA (field programmable gate array) is a solution to the problem, and has been spotlighted with the increase of the development cost of custom LSIs. FPGAs can be produced as general-purpose LSIs, and customers can program them to form desired circuits. Hence mask sets for approximately ten types of products depending on the final circuit scales are sufficient to respond to the requirements of various customers. However, although the circuit can be freely programmed, the basic circuit configuration is necessarily such that one block includes a plurality of logic cells, one of which is selected and activated for connection to the next block. Thus the circuit is wasteful, increasing the chip size. This results in a longer interconnect to the next circuit, which unfortunately delays signal transmission and decreases processing speed. As another drawback, because of the large chip size, the LSI price is considerably higher than the custom LSI of the same circuit scale.

The development cost and LSI pricing depend on various factors, which make simple comparison impossible. However, the development cost is dominated by the mask cost, and the LSI unit price is dominated by the chip size. Inferring with these taken into consideration, FPGAs require no development cost except for that associated with customer's design work because FPGAs need no masks for development, but the LSI unit price is nearly 10 times higher than that of custom LSIs. Hence FPGAs are not suitable to LSIs marketed in high volume because of the high LSI unit price, despite the small development cost.

To fill the gap therebetween, products named “structured ASICs” have emerged with considerably low development cost and relatively low unit price of mass-produced LSIs. Instead of transistors in gate arrays, structured ASICs include multigates as standard cells, previously constructed up to the lower aluminum interconnect process, and are put in stock. Then, in the upper aluminum process, desired gate outputs are picked up from a multigate and connected to the input terminals of the next multigate circuit to construct a circuit meeting customer's requirements. Advantageously, structured ASICs allow a circuit to be adapted to customer's requirements by the upper aluminum layer alone. Furthermore, the upper aluminum layer is constructed using low-precision masks, which results in low mask cost and hence decreases the development cost. However, a multigate includes many gates available for constructing a circuit, but only one of the gates is actually used. Hence the circuit is wasteful, limiting improvement in the degree of integration. Thus the unit price of mass-produced LSIs is higher than that for embedded arrays.

Next, the challenge of increasing the degree of integration was addressed by structured ASICs with custom-designed megacells such as commonly-used CPUs or memories installed therein. However, because of customers' diverse demands, what kind of megacell to install is important in product planning, and numerous matrices need to be developed to meet customers' demands. As compared with embedded arrays, the unit price of mass-produced LSIs remains higher, and the development cost remains lower. Hence, structured ASICs are suitable to electronic equipment in small-lot production.

With the recent rapid progress of downscaling and higher integration in semiconductor products, the development cost rises with the soaring mask cost of embedded arrays. Thus the market of embedded array products is focused on a large amount of mass-produced equipment. There has been a demand for a technique of reducing the mask cost of embedded arrays to hold down the development cost.

JP-A 2002-184949 (Kokai) discloses a method for manufacturing a semiconductor device, comprising the step of performing a second exposure on a resist film by using a second photomask patterned with a second interconnect layer serving for connecting a first interconnect layer, and the step of developing the resist film and using the developed resist film as a mask to form the first interconnect layer and the second interconnect layer. This method can reduce the work of reticle replacement in manufacturing integrated circuits.

### SUMMARY OF THE INVENTION

According to an aspect of the invention, there is provided a semiconductor integrated circuit including: at least one first circuit portion including a first interconnect or a diffusion layer formed by exposure using a high-precision mask; and at least one second circuit portion including a second interconnect or a diffusion layer formed by exposure using a first low-precision mask having a lower precision than the high-precision mask.

According to another aspect of the invention, there is provided a method for manufacturing a semiconductor integrated circuit, including: preparing at least one high-precision mask and at least one low-precision mask having a lower precision than the high-precision mask, which are operable to form an interconnect or a diffusion layer; performing exposure on a prescribed circuit portion of the semiconductor integrated circuit using the high-precision mask to form the prescribed circuit portion; and performing exposure on another circuit portion of the semiconductor integrated circuit outside the prescribed circuit portion using the low-precision mask to form the other circuit portion.

### BRIEF DESCRIPTION OF THE DRAWINGS

FIG. 1 is a schematic cross-sectional view of an embedded array described in this embodiment.

FIG. 2 shows a plan view (FIG. 2A) and a cross-sectional view (FIG. 2B) illustrating transistors at the boundary between a megacell and a random logic of the embedded array of FIG. 1.

FIG. 3 is a plan view showing a high-precision mask and a low-precision mask used in fabricating the embedded array of FIG. 1.

FIG. 4 is a flow chart illustrating an exposure process used in fabricating the embedded array of FIG. 1.

FIG. 5 shows a plan view (FIG. 5A) illustrating the interconnection between interconnects in the high-precision mask and interconnects in the low-precision mask in this embodiment, and a plan view (FIG. 5B) illustrating the finished aluminum interconnects.

FIG. 6 is a cross-sectional view of an embedded array including two types of hard megacells.

FIG. 7A is a plan view of a first high-precision mask used for the embedded array.

FIG. 7B is a plan view of a second high-precision mask used for the embedded array.

FIG. 7C is a plan view of a low-precision mask used for the embedded array.

FIG. 8 is a flow chart illustrating an exposure process of this embodiment.

FIG. 9 is a schematic plan view of a structured ASIC described in this embodiment.

FIG. 10 includes schematic plan views showing a mask for a multigate (FIG. 10A), a mask for a CPU (FIG. 10B), and a mask for a megacell (FIG. 10C) in the structured ASIC of FIG. 9.

FIG. 11 is a flow chart illustrating an exposure process of this embodiment.

FIG. 12 is a schematic cross-sectional view of a structured ASIC described in this embodiment.

FIG. 13 is a schematic plan view showing examples of installing megacells in the structured ASIC described in this embodiment.

### DETAILED DESCRIPTION OF THE INVENTION

Aspects of the invention will now be described with reference to embodiments.

### First Embodiment

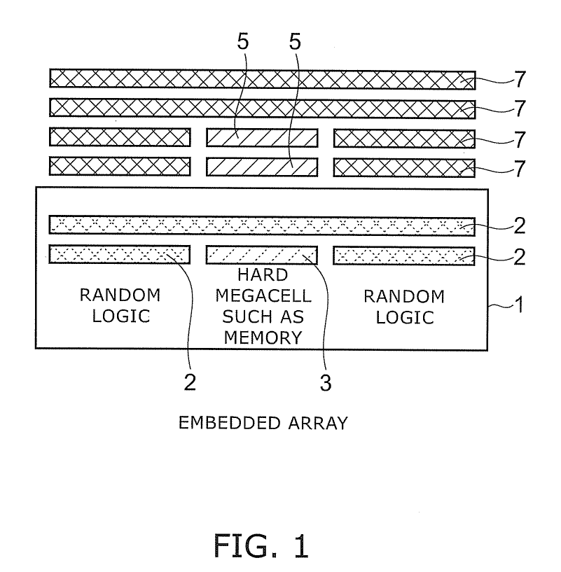

A first embodiment is described with reference to FIGS. 1 to 5.

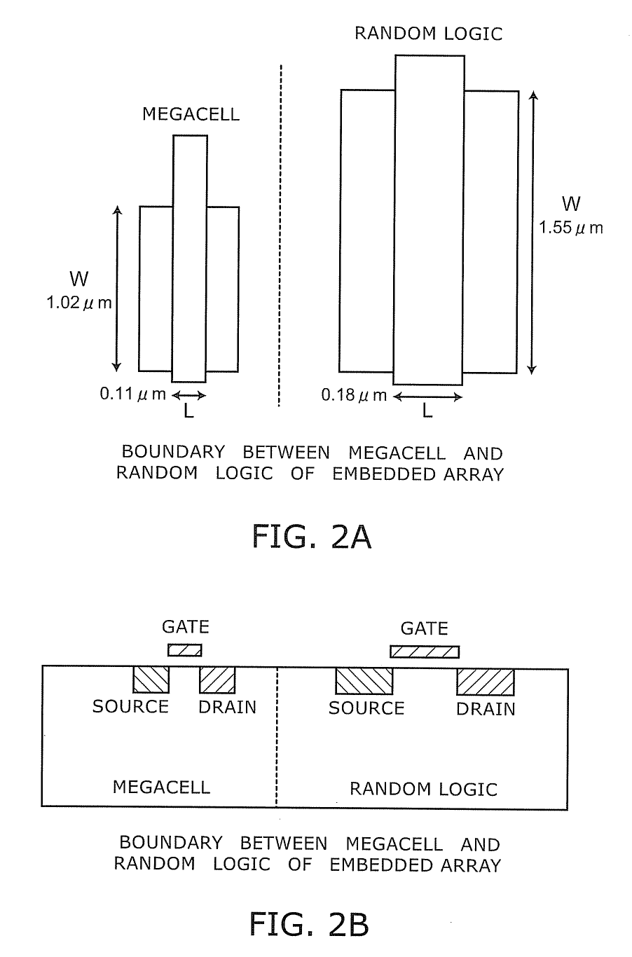

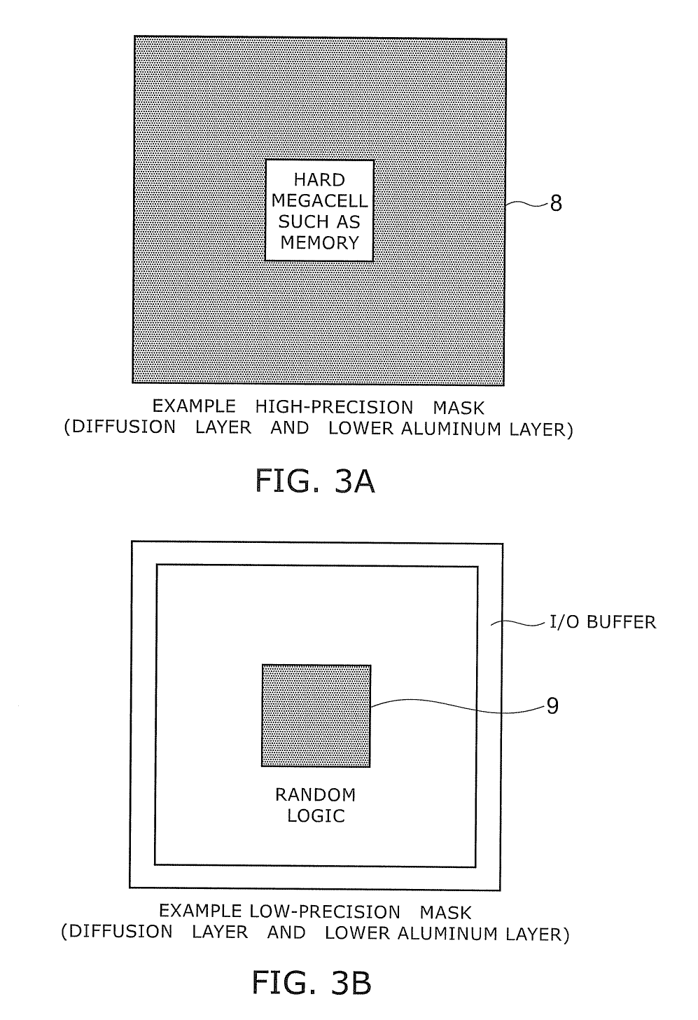

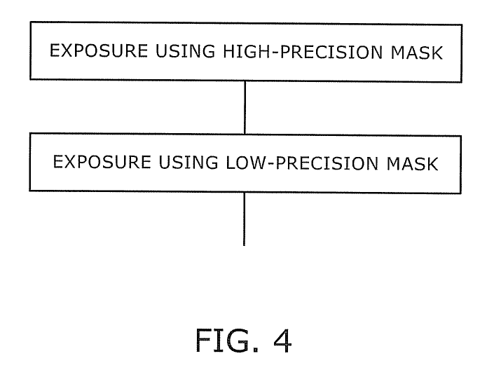

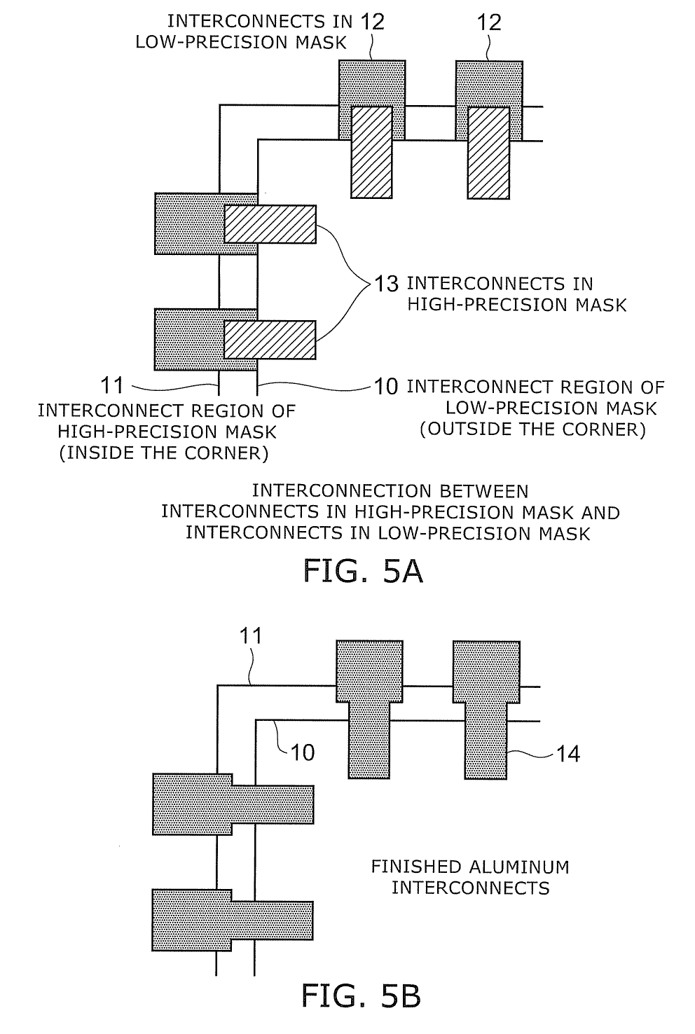

FIG. 1 is a schematic cross-sectional view of an embedded array described in this embodiment. FIG. 2 shows a plan view (FIG. 2A) and a cross-sectional view (FIG. 2B) illustrating transistors at the boundary between a megacell and a random logic of the embedded array of FIG. 1. FIG. 3 is a plan view showing a high-precision mask and a low-precision mask used in fabricating the embedded array of FIG. 1. FIG. 4 is a flow chart illustrating an exposure process used in fabricating the embedded array of FIG. 1. FIG. 5 shows a plan view (FIG. 5A) illustrating the interconnection between interconnects in the high-precision mask and interconnects in the low-precision mask in this embodiment, and a plan view (FIG. 5B) illustrating the finished aluminum interconnects.

This embodiment uses an embedded array as an example of the semiconductor integrated circuit.

Embedded arrays can be adapted to various customers. However, high-precision masks need to be designed and fabricated for each customer product, and unfortunately result in increased development cost. If high-precision masks can be standardized to eliminate the need of design and fabrication for each product, custom LSIs can be constructed at low development cost using only low-precision masks. Typically, the mask cost can be reduced to approximately 40% by doubling the interconnect width and the space width of a high-precision mask portion and using a low-precision mask for manufacturing.

Consider a case where 42 masks are required, 12 of which need to be high-precision masks, and one high-precision mask costs 2 million yen. Then the mask cost is 48 million yen for constructing conventional embedded arrays, but can be reduced 30% to 33.6 million yen for construction based on low-precision masks alone. If the low-precision mask is shifted to even lower precision, the mask cost can be reduced 60%. With regard to the chip area, assume a case where the nonstandard circuit portion accounts for 20%. Assuming that the area of this portion needs to be doubled, the overall area increases to 120%. The LSI cost also increases to this level.

In typical structured ASICs, standard circuits are packed into a narrow space by making full use of fine interconnection. However, the other random logic portion is based on complex logic circuits, where desired logics for use are selected from numerous logics prepared in advance. Thus the circuit is wasteful, hence increasing the chip area. This results in a longer distance to the next circuit, which increases the length of interconnects. The signal transmission speed also decreases in proportion to the interconnect length, and hence the operating speed slows down. With regard to custom LSIs, FPGAs, structured ASICs, universal arrays, and other gate arrays and standard cells in general, the basic characteristics of LSIs can be examined in advance to perform simulations to determine what circuit to be constructed can achieve what speed and functions, and a determination can be made as to whether LSIs meeting customer's requirements can be constructed. However, in view of the fact that the structured ASICs are typically used, it is considered generally that, except for the circuits specially designed for high-speed operation, the other circuits are not required to operate at very high speed. FPGAs exhibit this tendency more prominently. However, inferring from the acceptance of FPGAs by numerous users, it is often the case that the random logic portion is not generally required to operate at very high speed.

Hence, if the aluminum interconnect portion of one layer can be formed by using general-purpose high-precision masks for the standard circuit portion and using dedicated low-precision masks for the other circuits, then the development cost for mask fabrication does not increase significantly. Furthermore, because the performance of LSIs can be known in advance by simulation, there is also no need for concern about speed performance even in the case of using low-precision masks.

In conventional techniques, the bottom layer is a silicon wafer with transistors formed entirely therein by the diffusion process. This diffusion layer is manufactured partly by using high-precision dedicated masks and elsewhere by using low-precision dedicated masks. Two to four layers thereon include aluminum interconnects manufactured by high-precision dedicated masks. Two or three layers further thereon include aluminum interconnects based on low-precision dedicated masks. Thus all the layers from the diffusion layers to the aluminum interconnect layers are based on dedicated masks to form circuits meeting customer's requirements. However, the design and fabrication of high-precision dedicated masks result in high development cost.

FIG. 1 shows an embedded array described in this embodiment. A hard megacell (a cell with interconnects patterned into a fixed layout to achieve high performance and integration) such as CPU and SRAM and part of the input/output circuit are defined as standard circuits and prepared by fabricating high-precision shared masks. Furthermore, low-precision dedicated masks are fabricated by designing circuits in accordance with customer's requirements. In the low-precision mask, the minimum line width and the minimum space width between interconnects of the mask are wider than in the high-precision mask, but the manufacturing cost of the mask is significantly lower. In a silicon substrate 1, a diffusion layer 2 based on the low-precision dedicated mask and a diffusion layer 3 based on the high-precision shared mask are formed. On the silicon substrate 1 is formed a multilayer interconnection, in which the first layer and the second layer comprise aluminum interconnects 5 based on the high-precision shared masks and interconnects 7 based on the low-precision dedicated masks, and the third layer and the fourth layer located thereon comprise interconnects 7 based on the low-precision dedicated masks.

In the embodiment, two masks, i.e., one high-precision mask and one low-precision mask, are used to perform two exposure steps for one diffusion layer or aluminum layer, followed by developing the exposed resist layer with the high-precision mask and the low-precision mask at one time and by etching and other steps to construct the diffusion layer or aluminum interconnect layer. In the portion for constructing a hard megacell such as CPU and part of the high-speed input/output circuit portion, diffusion layers and aluminum interconnects are formed using the high-precision shared masks. In the random logic portion, diffusion layers and aluminum interconnects are formed using the low-precision dedicated masks.

FIG. 2 shows transistors in the megacell portion and the random logic of the embedded array described in this embodiment. The transistor in the megacell portion is formed using the high-precision shared masks, and the transistor in the random logic is formed using the low-precision dedicated masks.

The transistor formed using the high-precision shared masks has a gate length (L) of e.g. 0.11 μm and a gate width (W) of e.g. 1.02 μm. The transistor formed using the low-precision shared masks has a gate length (L) of e.g. 0.18 μm and a gate width (W) of e.g. 1.55 μm. The gate length of the transistor formed using the low-precision dedicated masks is larger than 0.11 μm, and the gate length of the transistor formed using the high-precision dedicated masks is 0.11 μm or less.

FIG. 3A shows an example of the high-precision mask, and FIG. 3B shows an example of the low-precision mask. In the high-precision mask, a light-shielding mask 8 is formed by blackening the portion outside the hard megacell such as memory and part of the input/output circuit to prevent light from leaking into the random logic portion and adversely affecting the formation of random logic circuits. In the figure, the input/output circuit is entirely covered with the light-shielding mask 8. However, in practice, it is patterned so that the portion of the input/output circuit for transistors and aluminum interconnects is blackened and the other portion is transparent.

Likewise, in the low-precision mask, a light-shielding mask 9 is formed by blackening the hard megacell portion and the remaining portion of the input/output circuit (FIG. 3B), and the random logic portion and the above portion of the input/output circuit for transistors and aluminum interconnects are patterned.

The embedded array of this embodiment requires two-step exposure in which an exposure step is performed using the high-precision mask and another exposure step is performed using the low-precision mask (FIG. 4).

FIG. 5A shows interconnect regions patterned in the high-precision mask and the low-precision mask. The figure shows interconnects 12 in the low-precision mask formed in the interconnect region (outside the corner) 10 of the low-precision mask and interconnects 13 in the high-precision mask formed in the interconnect region (inside the corner) 11 of the high-precision mask. In order to prevent the problem of broken interconnects due to any gap therebetween caused by mask misalignment, the patterning precision of the mask and the mask misalignment error in the exposure apparatus can be taken into consideration to allow the patterns to overlap by that amount, and the problem can be avoided in advance. FIG. 5B shows a finished configuration of the aluminum interconnects 14 formed using the patterns of FIG. 5A. Such interconnects 14 are formed by displacing the high-precision mask by approximately ⅓ of the overlapping portion to the right and bottom.

Low-precision masks are often used for the diffusion layer of a hard megacell. Hence, if the hard megacell and the random logic are both patterned into one low-precision mask used for exposure of the layer of the hard megacell, exposure can be performed at one time like conventional techniques. Thus a custom LSI including high-functionality circuits can be developed at low development cost.

Examples commonly implemented as hard megacells include SRAM (static random access memory), ROM (read only memory), DRAM (dynamic random access memory), and other memory devices, CPU (central processing unit), DSP (digital signal processor), JPEG (Joint Photographic Experts Group) and MPEG (Moving Picture Experts Group) devices, PLL (phase locked loop) circuits, UART (Universal Asynchronous Receiver Transmitter), USB (Universal Serial Bus), and PCI (Peripheral Component Interconnect) controllers. USB is an interface standard used to connect peripheral devices such as a mouse and a printer to a personal computer. It has the advantage of allowing connection of a maximum of 127 peripheral devices via a hub and allowing insertion and extraction during operation of a personal computer. USB 1.1, which has a maximum transfer rate of 12 Mbps, and USB 2.0 (Hi-Speed USB), which realizes a maximum of 480 Mbps, are widely used. UART, which is the acronym for Universal Asynchronous Receiver Transmitter, refers to a circuit for converting a parallel signal to a serial signal for output and converting an inputted serial signal to a parallel signal. It is mounted as an LSI chip on a mother board and an expansion card.

The PCI controller is a data transmitting/receiving circuit for data transfer in compliance with a standard developed by PCI SIG (Special Interest Group) led by Intel Corporation, US. The standard relates to a bus (data transmission channel) between parts inside a personal computer. The PCI bus has become widespread in place of the ISA bus, a previous industry standard, and is currently used in most personal computers.

As described above, this embodiment can provide a custom LSI capable of including various IPs in one chip to meet customer's requirements. The development cost can be reduced without compromising the high performance and high density of semiconductor integrated circuits installed therein.

### Second Embodiment

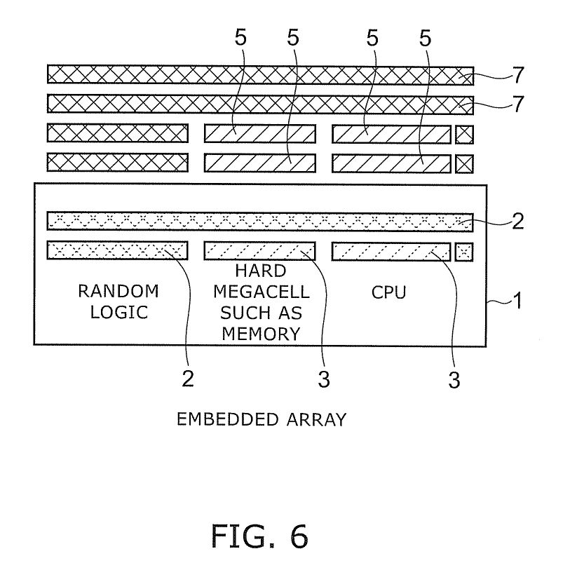

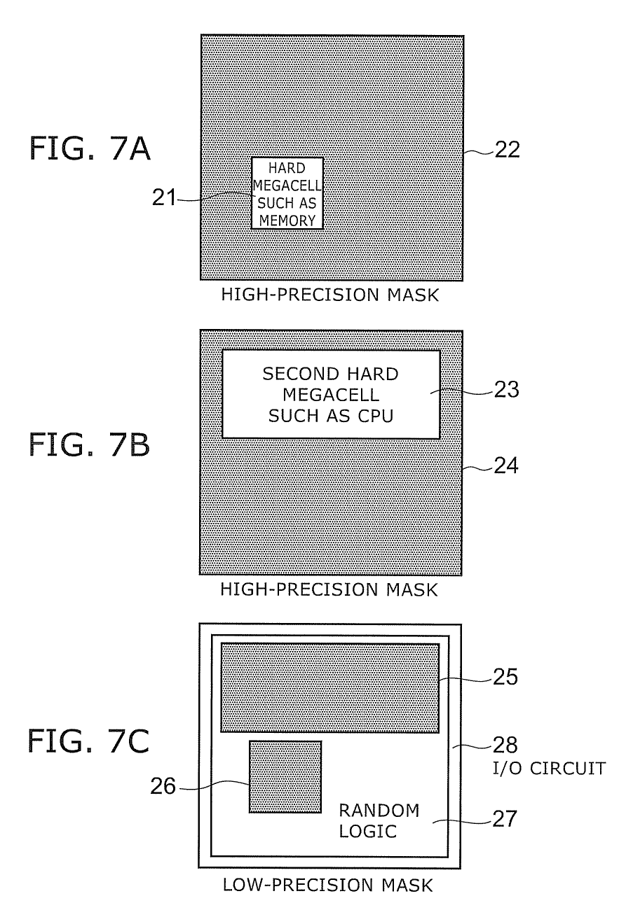

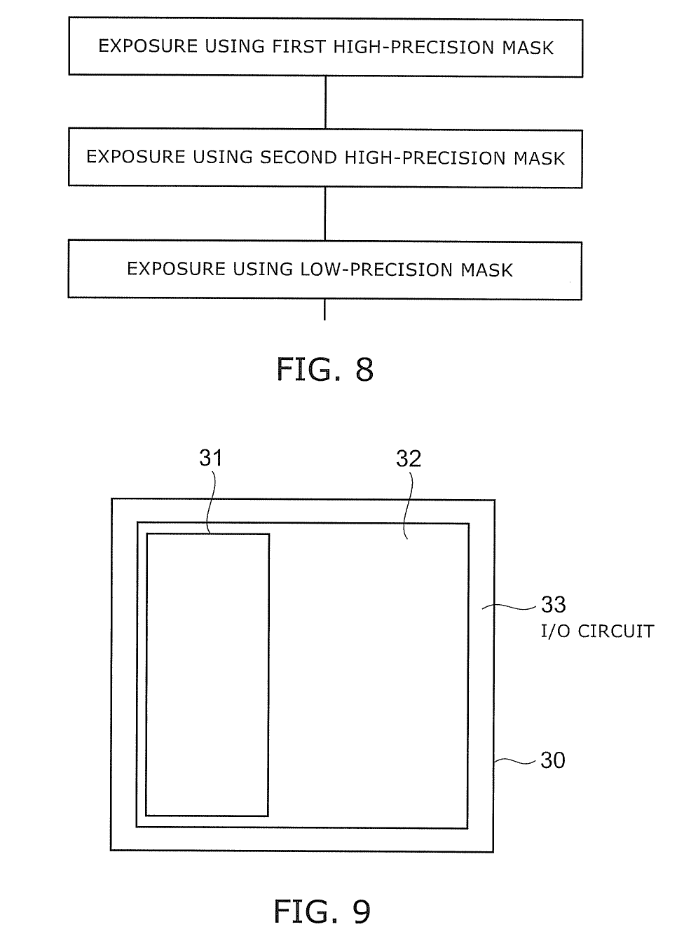

Next, a second embodiment is described with reference to FIGS. 6 to 8. FIG. 6 is a cross-sectional view of an embedded array including two types of hard megacells. FIG. 7A is a plan view of a first high-precision mask used for the embedded array. FIG. 7B is a plan view of a second high-precision mask used for the embedded array. FIG. 7C is a plan view of a low-precision mask used for the embedded array. FIG. 8 is a flow chart illustrating an exposure process of this embodiment.

In the hard megacell such as memory, the hard megacell such as CPU, and part of the input/output circuit, diffusion layers and aluminum interconnects are formed using high-precision shared masks. In the random logic portion, diffusion layers and aluminum interconnects are formed using low-precision dedicated masks.

FIG. 6 shows an embedded array described in this embodiment. In a silicon substrate 1, a diffusion layer 2 based on the low-precision dedicated mask and a diffusion layer 3 based on the high-precision shared mask are formed. On the silicon substrate 1 is formed a multilayer interconnection, in which the first layer and the second layer comprise first and second aluminum interconnects 5 based on the high-precision shared masks and interconnects 7 based on the low-precision dedicated masks, and the third layer and the fourth layer located thereon comprise interconnects 7 based on the low-precision dedicated masks.

In the embodiment, two masks, i.e., one high-precision mask and one low-precision mask, are used to perform three exposure steps for one diffusion layer or aluminum interconnect, followed by etching and other steps to construct the diffusion layer or aluminum interconnect. In the portion for constructing a hard megacell such as CPU and part of the high-speed input/output circuit portion, diffusion layers and aluminum interconnects are formed using the high-precision shared masks. In the random logic portion, diffusion layers and aluminum interconnects are formed using the low-precision dedicated masks.

FIG. 7A shows an example of the first high-precision mask 21 used for forming diffusion layers and aluminum interconnects in the hard megacell such as memory and part of the input/output circuit. In the first high-precision mask 21, a light-shielding mask 22 is formed by blackening the portion outside the hard megacell such as memory and part of the input/output circuit to prevent light from leaking into the random logic portion and the like and adversely affecting the formation of random logic circuits. In FIG. 7A, the input/output circuit is entirely covered with the light-shielding mask 22. However, in practice, it is patterned so that the portion of the input/output circuit for transistors and aluminum interconnects is blackened and the other portion is transparent.

FIG. 7B shows an example of the second high-precision mask 23 used for forming diffusion layers and aluminum interconnects in the second hard megacell such as CPU. The hard megacells are forbidden from overlapping each other. This also applies to the input/output circuit. In the second high-precision mask 23, a light-shielding mask 24 is formed by blackening the portion outside the second hard megacell such as CPU and part of the input/output circuit to prevent light from leaking into the random logic portion and the like and adversely affecting the formation of random logic circuits. In FIG. 7B, the input/output circuit is entirely covered with the light-shielding mask 24. However, in practice, it is patterned so that the portion of the input/output circuit for transistors and aluminum interconnects is blackened and the other portion is transparent.

FIG. 7C shows an example of the low-precision mask 27 used for forming diffusion layers and aluminum interconnects in the random logic. In the low-precision mask 27, a light-shielding mask 25, 26 is formed by blackening the second hard megacell portion and the first hard megacell portion, and the random logic portion 27 and the above portion of the input/output circuit 28 for transistors and aluminum interconnects are patterned.

The embedded array of this embodiment requires three-step exposure in which an exposure step is performed using the first high-precision mask, another exposure step is performed using the second high-precision mask, and finally, an exposure step is performed using the low-precision mask (FIG. 8). While either mask can be used first, the number of times of retrying exposure is reduced by first using the high-precision mask, which has a greater risk of failure of exposure.

As described above, this embodiment can provide a custom LSI capable of including various IPs in one chip to meet customer's requirements. The development cost can be reduced without compromising the high performance and high density of semiconductor integrated circuits installed therein.

### Third Embodiment

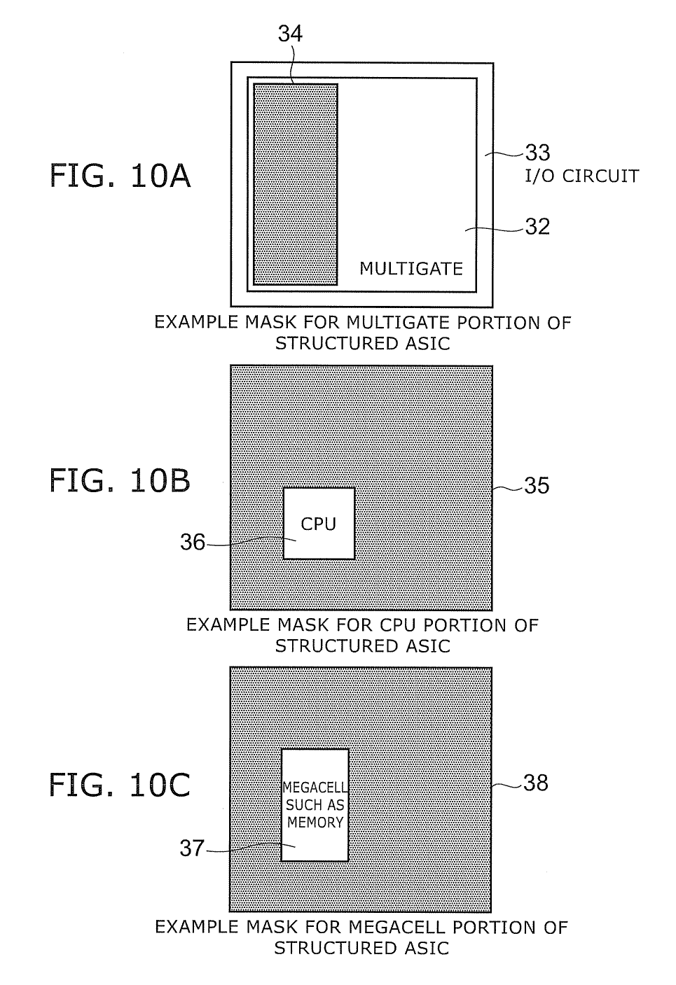

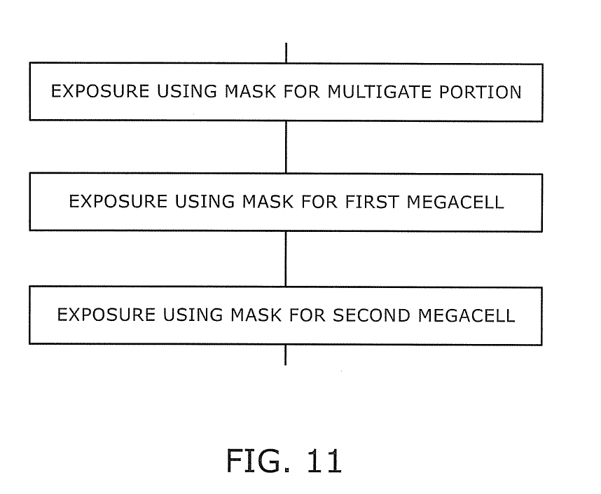

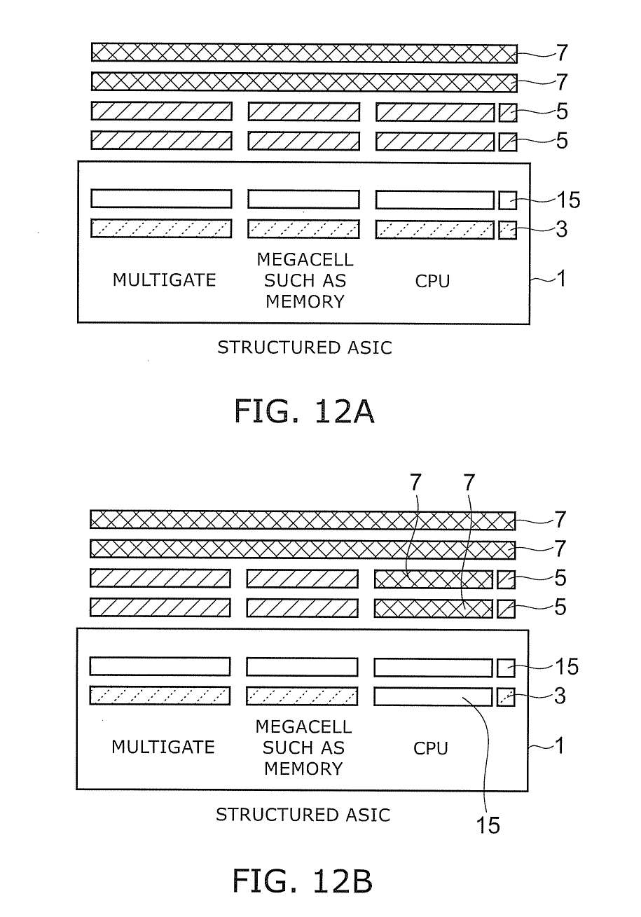

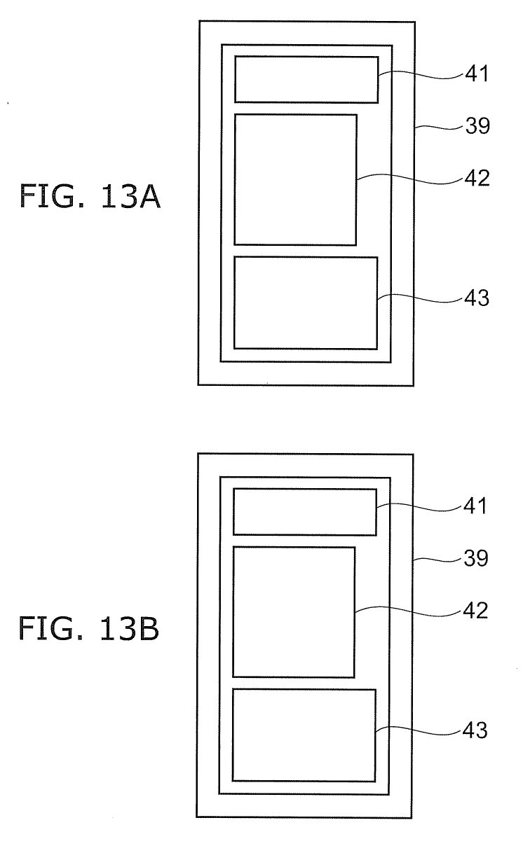

Next, a third embodiment is described with reference to FIGS. 9 to 13. FIG. 9 is a schematic plan view of a structured ASIC described in this embodiment. FIG. 10 includes schematic plan views showing a mask for a multigate (FIG. 10A), a mask for a CPU (FIG. 10B), and a mask for a megacell (FIG. 10C) in the structured ASIC of FIG. 9. FIG. 11 is a flow chart illustrating an exposure process of this embodiment. FIG. 12 is a schematic cross-sectional view of a structured ASIC described in this embodiment. FIG. 13 is a schematic plan view showing examples of installing megacells in the structured ASIC described in this embodiment.

This embodiment is characterized in that a structured ASIC is constructed by including desired megacells. In the conventional structured ASIC including megacells, an input/output circuit is placed at the periphery, a CPU or memory called a megacell is placed inside, and the gap therebetween is filled with multigate cells. With regard to masks for manufacturing the conventional structured ASIC, diffusion layers and up to lower aluminum layers are manufactured using shared masks, and the last upper aluminum layer is manufactured using low-precision dedicated masks.

The shared masks are based on high-precision masks as needed. Structured ASICs allow LSIs meeting customer's specification requirements to be constructed using only two or three low-precision masks, achieving low development cost. Furthermore, structured ASICs can be fabricated in advance up to lower aluminum interconnect layers, achieving short development time for prototypes. However, because the manufacturing is standardized up to the lower aluminum layers, the multigate cell portion for constructing a random logic includes many logics for processing some input signals, but only one of the logics is actually used. Hence the circuit is wasteful, increasing the chip size and the distance to the next multigate cell, which unfortunately decreases processing speed. To compensate for this drawback, a commonly-used megacell is included to increase the degree of integration and the overall circuit scale. However, megacells generally vary with applications. Furthermore, in the rapidly advancing field of electronic devices, products for the same purpose may vary in circuit scale and the megacell required is ever changing. Hence, structured ASICs cannot respond to customer's requirements without developing numerous matrices including various megacells. For example, even the memory alone has various types such as SRAM, ROM, and DRAM, each associated with some options for memory capacity, which result in numerous combinations. Furthermore, the multigate can be implemented in a variety of circuit scales, hence further increasing the number of combinations.

This embodiment can provide a structured ASIC including megacells in accordance with customer's requirements. Because shared masks can be used for layers up to lower aluminum interconnects, the structured ASIC can be developed at the same development cost as conventional structured ASICs while maintaining the performance of the high-speed portion.

FIG. 9 shows a structured ASIC according to this embodiment. An input/output circuit 33 is placed around a silicon chip 30, an area 31 for placing customer-specified megacells is provided inside, and the gap therebetween is filled with multigate cells 32.

FIG. 10 shows an example of mask fabrication for the structured ASIC of this embodiment. FIG. 10A shows a mask for exposure of the multigate cells 32 and the input/output circuit 33. A light-shielding mask 34 is formed by blackening the area available for installing customer-specified megacells to shield light. Next, FIG. 10B shows an example mask for exposure of a CPU 36 implemented as a megacell. A light-shielding mask 35 is formed by blackening the portion outside the circuit pattern of the CPU. Next, FIG. 10C shows an example mask for exposure of a megacell 37 such as memory. A light-shielding mask 38 is formed by blackening the portion outside the circuit pattern of the megacell such as memory.

The projection position of the megacell pattern of FIGS. 10B and 10C onto the chip can be freely changed by shifting the position offset after alignment of the mask. Hence one mask can be applied to various products having different chip sizes. The megacell circuits are often rectangular or square. However, the long side and the short side are difficult to control in length under the pursuit of high speed performance and integration density, hence resulting in various lengths in general. Thus, distributed placement of megacells is wasteful in space as well as causing concern as to whether the desired megacell is fit in. Hence it is efficient to allocate an area for megacells at one position.

Some types of multigate cells having different circuit scales can be prepared as part of the megacell. Then any unused area available for installing customer-specified megacells can be utilized as a multigate portion, hence eliminating waste in the circuit blank portion and improving the degree of integration.

FIG. 11 shows a method for exposure. First, exposure is performed using a mask patterned with the multigates 32 and the input/output circuit 33. Next, exposure is performed using a mask patterned with a first megacell (e.g., CPU) 36. Finally, exposure is performed using a mask patterned with a second megacell (e.g., memory) 37. Thus the increase in the number of megacells is addressed by increasing the number of times of exposure.

Here, the above exposure method needs to be performed for each exposure step up to lower aluminum interconnect layers. The upper aluminum interconnect layer can be processed by one exposure step as in conventional structured ASICs.

FIG. 12A shows an example usage of masks for the structured ASIC of this embodiment. Exposure for forming diffusion layers 3 using high-precision shared masks and exposure for forming diffusion layers 15 using low-precision shared masks are performed for each circuit of the multigate portion, the megacell such as memory, and the CPU. Exposure for forming lower aluminum interconnects 5 using high-precision shared masks is also performed for each circuit. Finally, exposure for forming upper aluminum interconnects 7 using low-precision dedicated masks is performed only once on the entire chip surface.

In the case of structured ASICs, the mask for the multigate and the input/output circuit can also be used as a shared mask. Hence use of high-precision masks does not increase the development cost for each particular product. Thus the multigate portion and the input/output circuit portion can also be processed by microfabrication.

Conversely, in the case of megacells, mask design and characterization are performed in compliance with design standards for microfabrication in the new generation. This requires a long development period, causing delay in launching new products. Hence use of old-generation masks for the megacell portion can expedite new product launching.

FIG. 12B shows an example usage of masks for the structured ASIC, where old-generation masks are used for part of the megacells. The old-generation masks are used in the CPU portion.

Exposure for forming diffusion layers 3 using high-precision shared masks and exposure for forming diffusion layers 15 using low-precision shared masks are performed for each circuit of the multigate portion, the megacell such as memory, and the CPU. Exposure for forming aluminum interconnects 5 as lower aluminum interconnects for the multigate portion and the megacell such as memory using high-precision shared masks is also performed for each circuit. Finally, exposure for forming upper aluminum interconnects 7 using low-precision dedicated masks is performed only once on the entire chip surface. In the circuit of the CPU, aluminum interconnects 7 based on low-precision dedicated masks are used as lower aluminum interconnects.

When the development of new-generation megacells is completed, the old-generation megacell masks can be replaced to upgrade the products halfway during production. In this case, if the positions of old-generation input/output terminals and power supplies remain unchanged, there is no need to newly fabricate masks for upper aluminum layers. Change in the positions, if any, can be addressed by modifying one VIA mask, which is a low-precision mask for connecting between the upper aluminum layer and the lower aluminum layer. At worst, upgrade is completed by modifying one more mask for the upper aluminum layer.

FIG. 13A shows an example arrangement of megacells in the megacell installation portion corresponding to FIG. 12A. A new-generation CPU 43 and an SRAM 42 are placed, and new-generation multigates 41 for filling the gap are placed in the remaining space. Multigates based on new-generation masks are placed around the megacell portion, and are covered with a light-shielding mask 39 during exposure of the megacell installation portion. This type of products can also be developed by using the present technique. Examples commonly implemented as megacells include SRAM (static random access memory), ROM (read only memory), DRAM (dynamic random access memory), and other memory devices, CPU (central processing unit), DSP (digital signal processor), JPEG (Joint Photographic Experts Group) and MPEG (Moving Picture Experts Group) devices, PLL (phase locked loop) circuits, UART (Universal Asynchronous Receiver Transmitter), USB (Universal Serial Bus), and PCI (Peripheral Component Interconnect) controllers.

FIG. 13B shows an example arrangement of megacells in the megacell installation portion corresponding to FIG. 12B. An old-generation CPU 43 and a new-generation SRAM 42 are placed, and new-generation multigates 41 for filling the gap are placed in the remaining space. Multigates based on new-generation masks are placed around the megacell portion, and are covered with a light-shielding mask 39 during exposure of the megacell installation portion. This type of products can also be developed by using the present technique.

As described above, according to this embodiment, a structured ASIC including megacells meeting customer's requirements can be developed at the same development cost as conventional structured ASICs without compromising its characteristics.

1. A semiconductor integrated circuit comprising:
at least one first circuit portion including a first interconnect or a diffusion layer formed by exposure using a high-precision mask; and
at least one second circuit portion including a second interconnect or a diffusion layer formed by exposure using a first low-precision mask having a lower precision than the high-precision mask.

2. The semiconductor integrated circuit according to claim 1, wherein a smallest transistor formed in the second circuit portion is larger than a smallest transistor formed in the first circuit portion.

3. The semiconductor integrated circuit according to claim 1, wherein a gate length of a smallest transistor formed in the second circuit portion is larger than a gate length of a smallest transistor formed in the first circuit portion.

4. The semiconductor integrated circuit according to claim 1, wherein the first circuit portion includes a third interconnect on the first interconnect or the diffusion layer formed by exposure using the high-precision mask portion, the third interconnect being formed by exposure using a second low-precision mask having a lower precision than the high-precision mask.

5. The semiconductor integrated circuit according to claim 1, wherein a pattern extending from the first circuit portion to the second circuit portion is provided at a boundary of the first and the second circuit portions, and a width of the pattern in the first circuit portion is smaller than a width of the pattern in the second circuit portion.

6. The semiconductor integrated circuit according to claim 1, wherein
the semiconductor integrated circuit is an embedded array, and the embedded array includes:
a megacell portion constituting the first circuit portion;
a gate array constituting the second circuit portion; and
an input/output circuit constituting the second circuit portion.

7. The semiconductor integrated circuit according to claim 6, wherein a smallest transistor formed in the second circuit portion is larger than a smallest transistor formed in the first circuit portion.

8. The semiconductor integrated circuit according to claim 6, wherein a gate length of a smallest transistor formed in the second circuit portion is larger than a gate length of a smallest transistor formed in the first circuit portion.

9. The semiconductor integrated circuit according to claim 6, wherein the first circuit portion includes a third interconnect on the first interconnect or the diffusion layer formed by exposure using the high-precision mask portion, the third interconnect being formed by exposure using a second low-precision mask having a lower precision than the high-precision mask.

10. The semiconductor integrated circuit according to claim 1, wherein
the semiconductor integrated circuit is a structured ASIC, the structured ASIC includes:
a megacell portion including the first circuit portion and the second circuit portion;
a multigate cell constituting the first circuit portion; and
an input/output circuit constituting the second circuit portion.

11. The semiconductor integrated circuit according to claim 10, wherein a smallest transistor formed in the second circuit portion is larger than a smallest transistor formed in the first circuit portion.

12. The semiconductor integrated circuit according to claim 10, wherein a gate length of a smallest transistor formed in the second circuit portion is larger than a gate length of a smallest transistor formed in the first circuit portion.

13. The semiconductor integrated circuit according to claim 10, wherein the first circuit portion includes a third interconnect on the first interconnect or the diffusion layer formed by exposure using the high-precision mask portion, the third interconnect being formed by exposure using a second low-precision mask having a lower precision than the high-precision mask.

14. A method for manufacturing a semiconductor integrated circuit, comprising:
preparing at least one high-precision mask and at least one low-precision mask having a lower precision than the high-precision mask, which are operable to form an interconnect or a diffusion layer;
performing exposure on a prescribed circuit portion of the semiconductor integrated circuit using the high-precision mask to form the prescribed circuit portion; and
performing exposure on another circuit portion of the semiconductor integrated circuit outside the prescribed circuit portion using the low-precision mask to form the other circuit portion.

15. The method for manufacturing a semiconductor integrated circuit according to claim 14, further comprising:
developing the exposed portion of the prescribed circuit portion and the another circuit portion at one time after performing exposure on the prescribed circuit portion and performing exposure on the another circuit portion.

16. The method for manufacturing a semiconductor integrated circuit according to claim 14, wherein the performing exposure on the another circuit portion is performed after performing exposure on the prescribed circuit portion.

17. The method for manufacturing a semiconductor integrated circuit according to claim 14, wherein the high-precision mask includes a first light-shielding portion corresponding to the another circuit portion, and the low-precision mask includes a second light-shielding portion corresponding to the prescribed circuit portion.

18. The method for manufacturing a semiconductor integrated circuit according to claim 14, further comprising performing exposure on the prescribed circuit portion of the semiconductor integrated circuit using a low-precision mask having a lower precision than the high-precision mask to form an interconnect.

19. The method for manufacturing a semiconductor integrated circuit according to claim 14, wherein the high-precision mask includes a first pattern extending from the prescribed circuit portion to the another circuit portion, and the low-precision mask includes a second pattern extending from the another circuit portion to the prescribed circuit portion.

20. The method for manufacturing a semiconductor integrated circuit according to claim 19, wherein a width of the first pattern is smaller than a width of the second pattern.
